(19) United States
(12) Patent Application Publication
(10) Pub. No.: US 2015/0184796 A1
(43) Pub. Date: Jul. 2, 2015

(54) SURFACE MOUNTING SYSTEMS AND METHODS

(71) Applicant: Innovelis, Inc., Sammamish, WA (US)

(72) Inventor: Eric John Wengreen, Sammamish, WA (US)

(73) Assignee: Innovelis, Inc., Sammamish, WA (US)

(21) Appl. No.: 14/146,178

(22) Filed: Jan. 2, 2014

(51) Int. Cl. F16M 13/02; H05K 7/02

(52) U.S. Cl. CPC F16M 13/02; H05K 7/02

(57) ABSTRACT

Mounting systems and methods can couple an electronic device to a surface (e.g., a wall, a ceiling, a desk, an entertainment center). In some embodiments, mounting systems can include a bar with a first anchor and a second anchor configured to couple to electronic devices.

### BACKGROUND

1. Field

Various embodiments disclosed herein relate to mounting systems and methods. Certain embodiments relate to mounting systems and methods to couple an electronic device to a surface, such as a wall or ceiling.

2. Description of Related Art

People often mount electronic devices on surfaces such as walls and ceilings. In some cases, people mount electronic devices to surfaces under desks and tables. Several prior-art mounting approaches include inserting two screws into a surface and then coupling the screws to holes in an electronic device. These prior-art mounting methods suffer from several difficulties. For example, people often struggle to insert the screws at precisely the distance apart necessary for the screws to fit simultaneously into holes of an electronic device. In some cases, the geometry of a screw fails to securely couple the electronic device to the wall. Thus, there is a need for mounting systems and methods that facilitate simpler and/or more secure coupling of electronic devices to surfaces such as walls and/or ceilings.

### SUMMARY

Several embodiments include a mounting system for coupling a device (such as an electronic device) to a surface (e.g., a wall, a ceiling, a desk, an entertainment center). In some embodiments, the surface is flat.

In several embodiments, a mounting system can include a bar configured to couple to the surface, wherein the bar comprises a left side and a right side. A first protrusion can protrude outward from the left side of the bar. The first protrusion can comprise a first protrusion width, a first protrusion length, and a first protrusion thickness. A mounting system can include a first head comprising a first head width, a first head length, and a first head thickness. The first protrusion can couple the first head to the left side of the bar. The first head can be configured to couple the mounting system to the device. The first head width can be greater than the first protrusion width. In several embodiments, the first head width is at least 50% greater than the first protrusion width; at least 90% greater than the first protrusion width; and/or less than 340% greater than the first protrusion width.

A second protrusion can protrude outward from the right side of the bar. The second protrusion can comprise a second protrusion width, a second protrusion length, and a second protrusion thickness. A second head can comprise a second head width, a second head length, and a second head thickness. The second protrusion can couple the second head to the right side of the bar. The second head can be configured to couple the mounting system to the device. The second head width can be greater than the second protrusion width. In some embodiments, the second head width is at least 40% greater than the second protrusion width.

Several embodiments include a mounting system for coupling an electronic device to a wall. Mounting systems can include a bar configured to couple to an external surface of the wall such that the bar protrudes outwardly from the wall. The bar can comprise a left portion and a right portion. A first anchor can be coupled to the left portion of the bar and a second anchor can be coupled to the right portion of the bar. The first anchor can be configured to couple the mounting system to the device via a first hole in the device, and the second anchor can be configured to couple the mounting system to the device via a second hole in the device.

In some embodiments, the first anchor comprises a first head configured to enter the first hole. The first head can comprise a first main portion and a first finger that protrudes upward relative to the first main portion. The first main portion can be at least 50% wider than the first finger; at least 75% wider than the first finger; at least 100% wider than the first finger; and/or less than 300% wider than the first finger. The second anchor can comprise a second head configured to enter the second hole. The second head can comprise a second main portion and a second finger that protrudes upward relative to the second main portion. The second main portion can be at least 50% wider than the second finger, at least 75% wider than the second finger, at least 100% wider than the second finger, and/or less than 300% wider than the second finger.

Several methods include coupling an electronic device comprising a first hole and a second hole to a wall. Methods can use any of the devices and systems described herein. Some methods include molding a bar comprising a left side, a right side, and a third hole. Several methods include coupling a first protrusion to the left side of the bar and coupling a second protrusion to the right side of the bar. Some methods include coupling a first head to the first protrusion and coupling a second head to the second protrusion (e.g., such that the first head and the second head are located between 40 millimeters and 290 millimeters apart). Several methods include inserting a screw through the third hole and coupling the bar to the wall via the screw. Some methods include orienting the bar such that the first protrusion and the second protrusion protrude outward (away from the wall). Several methods include orienting the bar such that the first head and the second head are located farther from the wall than the first protrusion and the second protrusion. Some methods include inserting the first head into the first hole of the electronic device and inserting the second head into the second hole of the electronic device.

Several methods include orienting the bar horizontally (relative to the floor). Some methods include orienting the bar vertically or at an angle (relative to the floor). In some methods, the wall is a ceiling.

Some methods include coupling the electronic device between the first head and a first platform (e.g., having a first flat outward-facing surface) and coupling the electronic device between the second head and a second platform (e.g., having a second flat outward-facing surface) to form a gap between the electronic device and at least a majority of the bar. This gap can be used to promote airflow between at least a portion of the bar and the electronic device.

### BRIEF DESCRIPTION OF THE DRAWINGS

Various embodiments are described while referencing the drawings included herein. The drawings illustrate generally by way of example, but not by way of limitation, various embodiments discussed herein. The drawings are not necessarily to scale. To increase the clarity of certain features and to facilitate various descriptions, the scale of some features has been exaggerated and some features have been omitted. Some drawings are diagrammatic or semi-diagrammatic. Like numerals indicate items throughout the views.

FIG. 1 illustrates a perspective view of a mounting system, according to some embodiments.

FIG. 2 illustrates a front view of the mounting system when the mounting system is coupled to a wall, according to some embodiments.

FIG. 3 illustrates a bottom view of the mounting system coupled to a wall via a fastener, according to some embodiments.

FIG. 4 illustrates a side view of the mounting system coupled to a surface, according to some embodiments.

FIG. 5 illustrates a cross-sectional view along line 5-5 from FIG. 4, according to some embodiments.

FIGS. 6 and 7 illustrate perspective views of the first head coupled to the first protrusion, according to some embodiments.

FIG. 8 illustrates a side view of a mounting system, according to some embodiments.

FIG. 9 illustrates a perspective view, which shows the backside of the mounting system, according to some embodiments.

### DETAILED DESCRIPTION

The following detailed description includes references to the accompanying drawings, which form a part of the detailed description. The drawings show, by way of illustration, specific embodiments in which various aspects may be practiced. These embodiments are described in enough detail to enable those skilled in the art to make, use, and practice the innovations, features, and advances described herein. In some cases, embodiments are referred to as “examples.”

Embodiments can be combined with portions and/or the entirety of other embodiments. Thus, features described in the context of one embodiment can be combined with portions of other embodiments. To eliminate unnecessary redundancy, many innovative features are not described in the context of every embodiment.

Various structural, logical, and electrical alterations, modifications, and substitutions can be made without departing from the scope of the inventions. The scope of current and future claims is not limited by the particular embodiments described herein. For example, many embodiments include optional steps, features, components, and assemblies. The structures, devices, components, and assemblies described herein can be embodied as integrated or separate components, devices, and structures.

The methods and processes described herein may be performed in orders that differ from the sequences disclosed in particular embodiments. The methods and processes described herein can be performed in any suitable order and are not necessarily limited to the order in which they are described in particular embodiments. The methods and processes described in various embodiments include optional steps. Thus, some method and process embodiments include only select portions of the method and process embodiments described herein.

Although certain benefits, advantages, and features are described herein, not all embodiments necessarily achieve these benefits, advantages, and features. For example, some embodiments are tailored to achieve some benefits, advantages, or features, but do not achieve other benefits, advantages, or features. No benefit, advantage, feature, component, assembly, device, structure, step, stage, or phase disclosed herein is essential or indispensable.

Several embodiments include a mounting system for coupling a device (such as an electronic device) to a surface (e.g., a wall, a ceiling, a desk, an entertainment center). In some embodiments, the wall is flat.

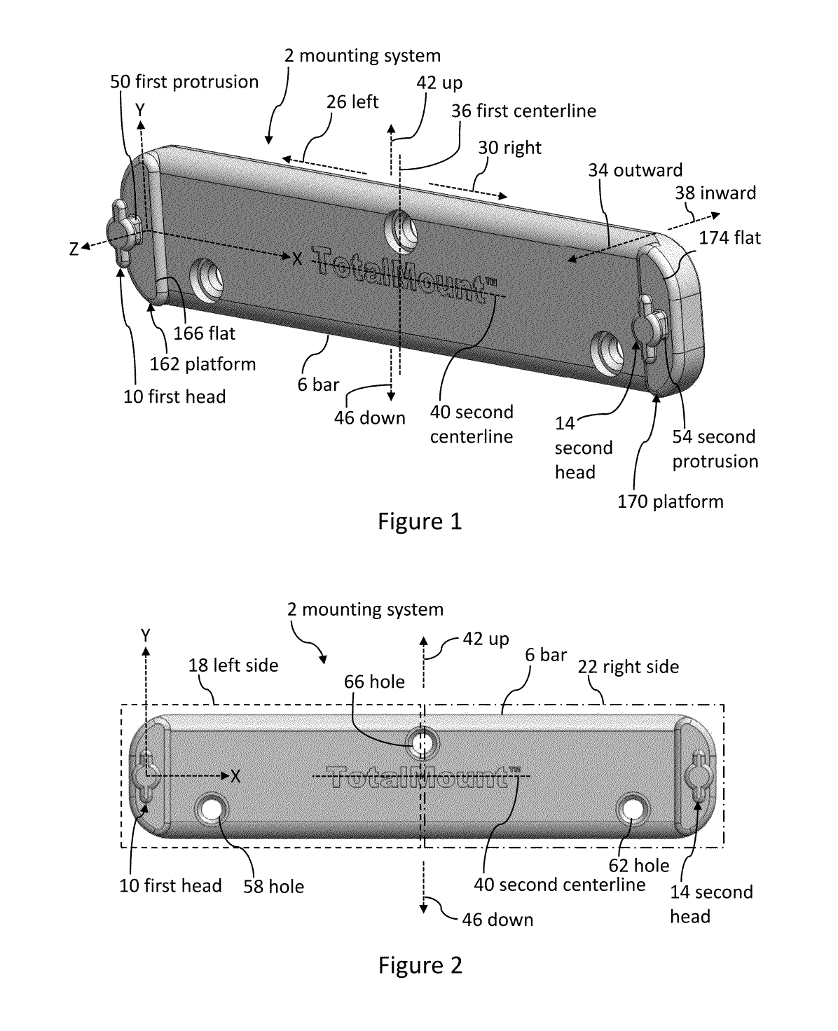

FIG. 1 illustrates a perspective view of a mounting system 2. The mounting system 2 can include a bar 6 configured to couple to a surface such as a wall or ceiling. As used herein, the term “bar” is used in a very broad sense. Bars used in mounting systems can include many different geometries and dimensions. Bars can be straight, curved, hallow, solid, include scaffolding, and/or any other shape suitable to couple a first head 10 to a second head 14. In addition to the bar 6, some embodiments include additional structures, components, and/or features coupled to the bar 6 and/or integrated with the bar 6. Bars can be made of many different materials including plastic, metal, and wood. Bars can be formed via many different manufacturing processes including molding, machining, welding, and extruding. In some embodiments, mounting systems 2 are molded from plastic, such as acrylonitrile butadiene styrene (“ABS”) plastic. In several embodiments, at least portions of mounting systems are molded from rubber. In some embodiments, the heads 10, 14 are molded from rubber and the bar 6 is molded from ABS.

As used herein, “left,” “right,” “outward,” “inward,” “up,” and “down” are defined based on the mounting system 2. FIG. 1 illustrates left 26, right 30, outward 34, inward 38, up 42, and down 46 relative to the mounting system 2. Inward 38 is the direction towards the wall when the mounting system 2 is coupled to the wall. Outward 34 is the direction away from the wall when the mounting system 2 is coupled to the wall. Left 26 is the left-hand direction when a person looks at the mounting system 2 when the mounting system 2 is mounted horizontally on a wall. Right 30 is the right-hand direction when a person looks at the mounting system 2 when the mounting system 2 is mounted horizontally on a wall. Up 42 is the direction away from the floor when the mounting system 2 is mounted horizontally on a wall. Down 46 is the direction towards the floor (i.e., towards the center of the earth) when the mounting system 2 is mounted horizontally on a wall. An object that protrudes in a first direction (e.g., outward) can also simultaneous protrude in another direction (e.g., up). As used herein, “up” and “upward” are used synonymously. As used herein, “down” and “downward” are used synonymously.

FIG. 1 illustrates a first centerline 36 of the mounting system 2 in the X direction. The first centerline 36 marks the center between the left 26 and right 30. In other words, the first centerline 36 marks the center between the left side 18 and the right side 22 of the mounting system 2 (shown in FIG. 2).

A second centerline 40 marks the center of the mounting system 2 in the Y direction. The first protrusion 50 and the second protrusion 54 can be located along the second centerline 40, upward 42 from the second centerline 40, or downward 46 from the second centerline 40.

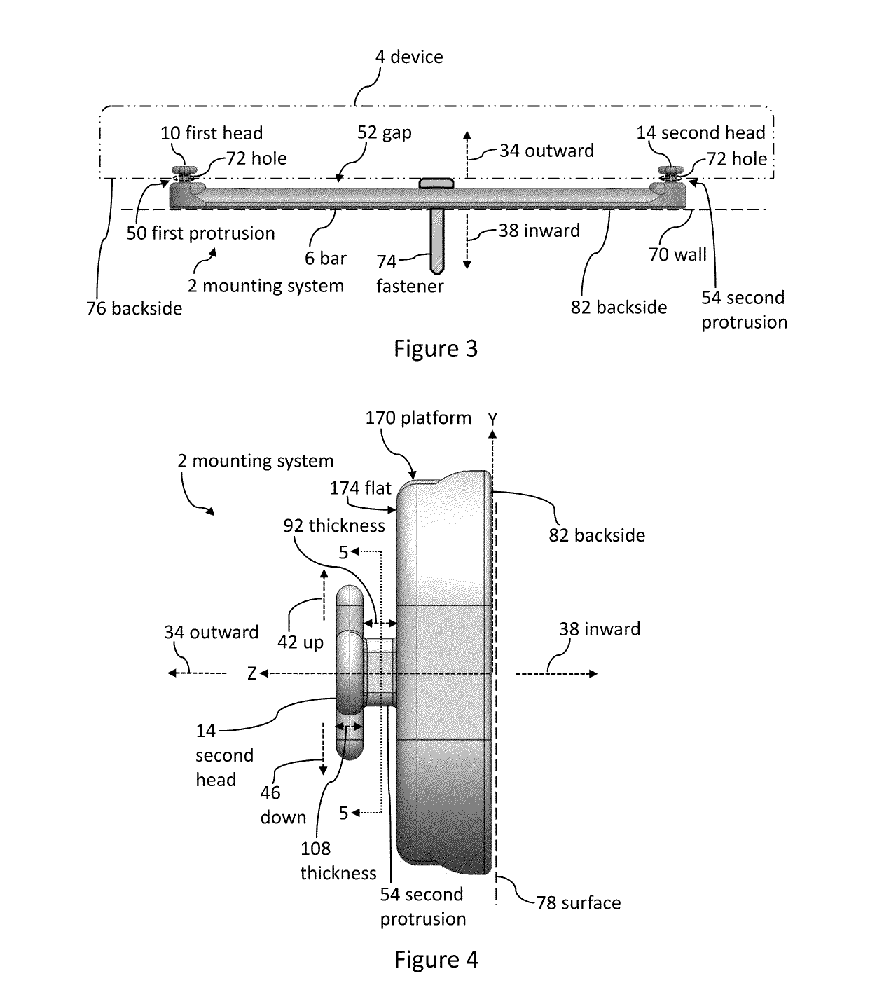

FIG. 1 illustrates a Cartesian coordinate system with perpendicular lines X, Y, and Z. The origin of X, Y, and Z is on the backside 82 (i.e., inward side) of the mounting system 2 such that the origin would be located on the mounting surface (e.g., the wall to which the mounting system 2 is coupled). The backside 82 of the mounting system 2 is labeled in FIG. 3. The X direction extends between the first protrusion 50 and the second protrusion 54 (e.g., between the first head 10 and the second head 14), although the X line is actually on the backside of the mounting system 2 and does not necessarily intersect with the first protrusion 50 and the second protrusion 54. The Y direction extends upward (i.e., parallel to the upward direction 42). The Z direction extends outward 34.

FIG. 2 illustrates a front view of the mounting system 2 when the mounting system 2 is coupled to a wall. The bar 6 is oriented horizontally in FIG. 2. The bar 6 comprises a left side 18 and a right side 22, which are labeled in FIG. 2 by boxes with dashed lines.

The mounting system 2 can include holes through which fasteners (e.g., nails, screws, pins, tacks) can be placed to couple the mounting system 2 to a wall. A first hole 58 can be located on the left side 18, above the second centerline 40, below the second centerline 40, and/or along the second centerline 40. A second hole 62 can be located on the right side 22, above the second centerline 40, below the second centerline 40, and/or along the second centerline 40. A third hole 66 can be located along the first centerline 36 (shown in FIG. 1), above the second centerline 40, below the second centerline 40, and/or along the second centerline 40. In some embodiments, screws are used with drywall anchors to couple the mounting system 2 to drywall. Some embodiments use one hole, two holes, three holes, four holes, five holes, and/or six or more holes.

FIG. 3 illustrates a bottom view of the mounting system 2 coupled to a wall 70 via a fastener 74 (e.g., a nail, a screw, a pin, a tack). The wall 70 can be the wall of a building or structure used to shelter people. For example, the wall 70 can be a wall of an office building, home, business, or warehouse. For clarity, FIG. 3 illustrates the head of the fastener 74 protruding outward 34 from the bar 6, but in several embodiments, the head of the fastener rests inside a portion of the bar 6 such that the head of the fastener does not protrude outside of the bar 6 when the fastener is fully inserted into the bar 6. Several embodiments use more than one fastener 74. The backside 82 (i.e., the inward side) of the mounting system 2 contacts the wall 70 directly in FIG. 3.

As illustrated in FIG. 3, the first head 10 and the second head 14 can enter holes 72 in the device 4 (e.g., an electronic device). The first head 10 and the second head 14 can enter holes 72 in the backside 76 of the device 4, wherein the backside 76 (i.e., the inward side) of the device 4 is the side of the device 4 that faces the wall 70.

FIG. 4 illustrates a side view of the mounting system 2 coupled to a surface 78, which can be a wall, a ceiling, a desk, furniture, an entertainment center, or another object suitable for holding the mounting system 2. The second protrusion 54 protrudes outward 34 from the right side 22 of the bar 6 (labeled in FIG. 2).

The second protrusion 54 can couple the second head 14 to the bar 6 (labeled in FIG. 3). The second head 14 can be configured to couple the mounting system 2 to a device, such as an electronic device. In some embodiments, the electronic device comprises a router configured to send data between computer networks (e.g., a wireless broadband router with internal antennas made by MEDIALINK PRODUCTS, LLC). Some routers can wirelessly provide Internet access.

The second head 14 can be oriented perpendicularly relative to the second protrusion 54. The second protrusion can be oriented perpendicularly relative to the wall 70 (shown in FIG. 3).

Although embodiments can include many different dimensional ranges, in some embodiments, the thickness 92 of the second protrusion 54 is less than 7 mm and/or the thickness 108 of the second head 14 is less than 7 mm. In several embodiments, the thickness 92 of the second protrusion 54 is less than 4 mm and/or the thickness 108 of the second head 14 is less than 4 mm.

Referring now to FIGS. 1 and 4, some mounting systems include a first platform 162, which can include a first flat outward-facing surface 166. The first platform 162 can couple the first protrusion 50 to the bar 6. Several embodiments include a second platform 170 having a second flat outward-facing surface 174. The second platform 170 can couple the second protrusion 54 to the bar 6. The first platform 162 and the second platform 174 can protrude outward from the bar 6 to enable airflow between the device 4 and the bar 6.

The platforms 162, 170 can protrude outward 34. In some embodiments, one or more platforms 162, 170 protrude farther outward than at least some other outer portions of the bar 6 located between the platforms 162, 170 to create a gap 52 (shown in FIG. 3). The gap 52 can enable airflow between the device 4 and the mounting system 2.

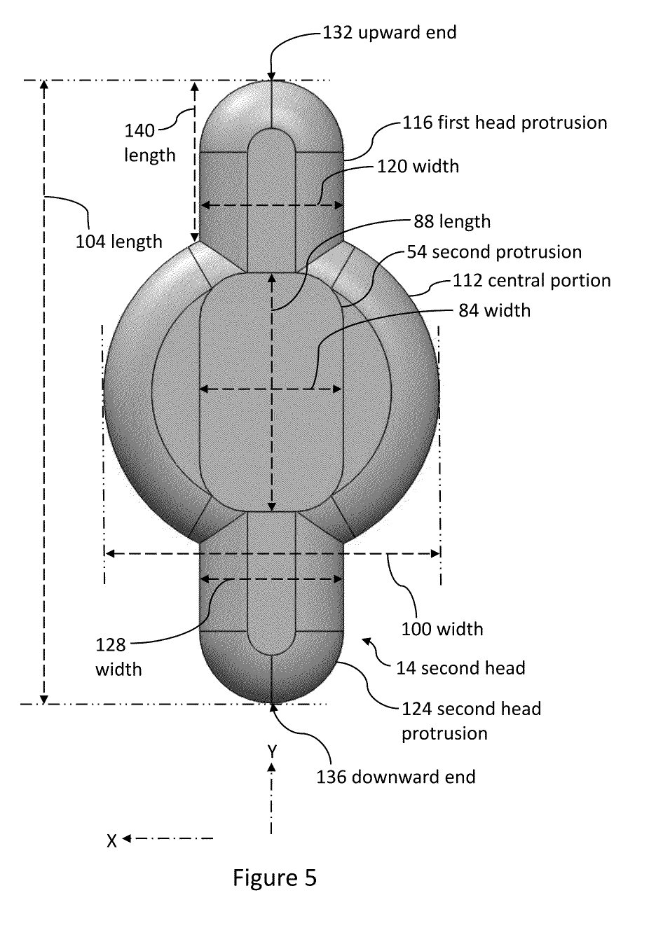

FIG. 5 illustrates a cross-sectional view along line 5-5 from FIG. 4. X and Y directions are shown in FIG. 5 for clarity, but the origin of X and Y is not shown in FIG. 5. The second protrusion 54 can comprise a second protrusion width 84, a second protrusion length 88, and a second protrusion thickness 92 (shown in FIG. 4).

“Width,” length,” and “thickness” are defined herein based on how they are measured. As used herein, “width” is measured in the left 26 to right 30 direction (i.e., the X direction), “length” is measured in the up 42 direction (i.e., the Y direction), and “thickness” is measured in the outward 34 direction (i.e., the Z direction).

The second head 14 can comprise a second head width 100, a second head length 104, and a second head thickness 108 (shown in FIG. 4). As used herein, the head width 100 is the maximum width of the head, the first head length 104 is the maximum length of the head, and a first head thickness 108 is the maximum thickness of the head.

The second head width 100 can be greater than the first protrusion width 84. In several embodiments, the second head width 100 is at least 50% greater than the first protrusion width 84; at least 90% greater than the first protrusion width 84; and/or less than 240% greater than the first protrusion width 84.

The second head length 104 can be greater than the second protrusion length 88. In several embodiments, the second head length 104 is at least 40% greater than the second protrusion length 88; at least 70% greater than the second protrusion length 88; at least 90% greater than the second protrusion length 88; and/or less than 240% greater than the second protrusion length 88.

In some embodiments, the second protrusion 54 has a circular cross section. In some embodiments, the second protrusion 54 has a square cross section with rounded corners. The length 88 of the second protrusion 54 can be at least 30% greater than the width 84 of the second protrusion 54; at least 50% greater than the width of the second protrusion 54; at least 70% greater than the width 84 of the second protrusion 54; and/or less than 300% greater than the width 84 of the second protrusion 54.

In several embodiments, the length 104 of the second head 14 is at least 25% greater than the width 100 of the second head 14; at least 20% greater than the width 100 of the second head 14; at least 40% greater than the width 100 of the second head 14; at least 60% greater than the width 100 of the second head 14; and/or less than 300% greater than the width 100 of the second head 14.

Various embodiments use diverse head and protrusion shapes. Some head embodiments use teardrop shapes and keyhole shapes.

The embodiments described herein regarding the second head 14 and second protrusion 54 can also apply to the first head 10 and the first protrusion 50 (shown in FIG. 1). Some embodiments include additional heads and protrusions that can be similar to any of the first and second heads, and first and second protrusions described herein.

The second head 14 can include a central portion 112. The central portion width is equal to width 100 in FIG. 5 because the central portion 112 is the widest portion of the second head 14 in the embodiment illustrated in FIG. 5. In some embodiments, the central portion 112 is not the widest portion of the second head 14.

The second head 14 can include a first head protrusion 116 that protrudes upward relative to the central portion 112. The first head protrusion 116 has a width 120, which is the widest width of the first head protrusion 116. The central portion 112 can couple the second head protrusion 14 to the second protrusion 54. In several embodiments, the width 100 of the central portion 112 is at least 25% greater than the width 120 of the first head protrusion 116. In several embodiments, the width 100 of the central portion 112 is at least 50% greater than the width 120 of the first head protrusion 116. In some embodiments, the width 100 of the central portion 112 is at least 70% greater than the width 120 of the first head protrusion 116 and/or less than 300% greater than the width 120 of the first head protrusion 116.

In the embodiment illustrated in FIG. 5, the central portion 112 is approximately circular. The central portion 112 comprises a left side and a right side. The left side of the central portion 112 can be curved and the right side of the central portion 112 can be curved (e.g., as illustrated in FIG. 5). In some embodiments, the first head protrusion 116 comprises a left side and a right side. The left side of the first head protrusion 116 can be straight and the right side of the first head protrusion 116 can be straight (e.g., as illustrated in FIG. 5).

The second head 14 can include a second head protrusion 124 that protrudes downward relative to the central portion 112 (e.g., downward relative to a portion of the mounting system 2 that couples the second head 14 to the base 6). The second head protrusion 124 can include a width 128. The central portion 112 can couple the second head protrusion 124 to the second protrusion 54. The width 100 of the central portion 112 can be at least 40 percent greater than the width 128 of the second head protrusion 124. The width 100 of the central portion 112 can be at least 80 percent greater than the width 128 of the second head protrusion 124.

In some embodiments, the first head protrusion 116 comprises an upward end 132, and the second head protrusion 124 comprises a downward end 136. The upward end 132 can be curved and the downward end 136 can be curved.

The width 120 of the first head protrusion 116 can be within plus or minus 10%; plus or minus 20%; and/or plus or minus 30% of the width 128 of the second head protrusion 124. In some embodiments, the width 120 of the first head protrusion 116 is equal to the width 128 of the second head protrusion 124. Some embodiments include a first head protrusion 116 but do not include a second head protrusion 124. In several embodiments, the first head protrusion 116 and the second head protrusion 124 are coplanar (e.g., as illustrated in FIG. 4).

In several embodiments, the length 140 of first head protrusion 116 is at least 1 millimeter (“mm”); at least 2 mm; and/or less than 9 mm. In some embodiments, the length of the second head protrusion 124 is at least 1 mm; at least 2 mm; and/or less than 9 mm. The length 140 of the first head protrusion 116 can be equal to, greater than, and/or at least 1 mm greater than the length of the second head protrusion 124. In several embodiments, the first head protrusion 116 is located on an opposite end of the second head 14 relative to the second head protrusion 124.

In some embodiments, the length 88 of the second protrusion 54 is at least 25% larger and/or at least 50% larger than the width 84 of the second protrusion 54. In several embodiments, the second protrusion 54 is oriented such that its length 88 is oriented in line with the first head protrusion 116 such that the length 88 of the second protrusion 54 and the length 140 of the first head protrusion 116 are oriented parallel to the Y-Z plane (e.g., as illustrated in FIG. 5).

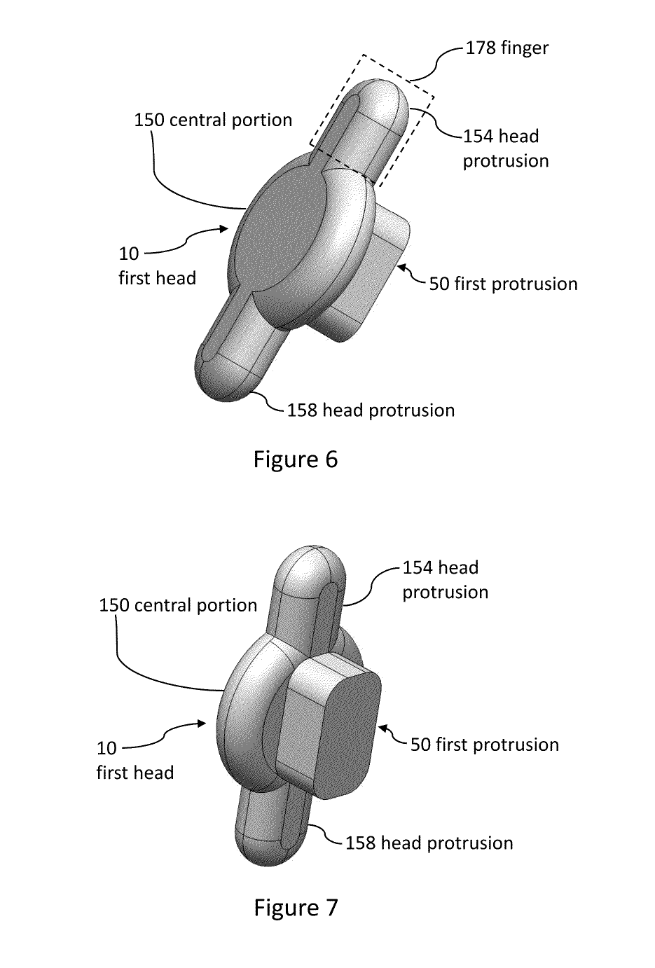

FIGS. 6 and 7 illustrate perspective views of the first head 10 coupled to the first protrusion 50. The rest of the mounting system 2 is hidden in FIGS. 6 and 7.

Several embodiments include a mounting system for coupling an electronic device to a wall. Mounting systems can include a bar configured to couple to an external surface of the wall such that the bar protrudes outwardly from the wall (e.g., as illustrated in FIG. 3). The bar can comprise a left portion (e.g., 18 in FIG. 2) and a right portion (e.g., 22 in FIG. 2). A first anchor can be coupled to the left portion of the bar, and a second anchor can be coupled to the right portion of the bar. Referring now to FIGS. 1 and 2, the first anchor can include the first head 10 and the first protrusion 50. The second anchor can include the second head 14 and the second protrusion 54. The first anchor can be configured to couple the mounting system to the device via a first hole in the device, and the second anchor can be configured to couple the mounting system to the device via a second hole in the device.

In some embodiments, the first anchor comprises a first head 10 configured to enter the first hole. The first head 10 can comprise a first main portion and a first finger 178 (labeled in FIG. 6) that protrudes upward relative to the first main portion (e.g., the central portion 150). As used herein, a finger means a protrusion that extends from a main portion of a head.

The first main portion can be at least 50% wider than the first finger; at least 75% wider than the first finger; at least 100% wider than the first finger; and/or less than 220% wider than the first finger. The second anchor can comprise a second head configured to enter the second hole. The second head can comprise a second main portion and a second finger that protrudes upward relative to the second main portion. The second main portion can be at least 50% wider than the second finger; at least 75% wider than the second finger; at least 100% wider than the second finger; and/or less than 220% wider than the second finger.

Several methods include coupling an electronic device comprising a first hole and a second hole to a wall. Methods can use any of the devices and systems described herein (e.g., any item illustrated in FIGS. 1-9) and/or additional or alternative mounting systems, surfaces, and devices. Some methods include forming (e.g., molding) a bar comprising a left side, a right side, and a third hole. Several methods include coupling a first protrusion to the left side of the bar and coupling a second protrusion to the right side of the bar. Some methods include coupling a first head to the first protrusion and coupling a second head to the second protrusion (e.g., such that the first head and the second head are located between 40 millimeters and 290 millimeters apart). Several methods include inserting a screw through the third hole and coupling the bar to the wall via the screw. Some methods include orienting the bar such that the first protrusion and the second protrusion protrude outward (away from the wall). Several methods include orienting the bar such that the first head and the second head are located farther from the wall than the first protrusion and the second protrusion. Some methods include inserting the first head into the first hole of the electronic device and inserting the second head into the second hole of the electronic device.

Several methods include orienting the bar horizontally (relative to the floor). Some methods include orienting the bar vertically or at an angle (relative to the floor). In some methods, the wall is a ceiling.

Some methods include coupling the electronic device between the first head and a first platform (e.g., having a first flat outward-facing surface) and coupling the electronic device between the second head and a second platform (e.g., having a second flat outward-facing surface) to form a gap between the electronic device and at least a majority of the bar. This gap can be used to promote airflow between at least a portion of the bar and the electronic device.

Several methods include orienting the bar 6 horizontally such that the first head 10 and the second head 14 are located an equal distance from the floor (e.g., from the center of the earth). Some methods include orienting the first protrusion 50 and/or the second protrusion 54 perpendicularly relative to a wall (e.g., such that the first protrusion 50 and the second protrusion 54 protrude straight out from the wall). Several methods include orienting the bar 6 such that the first head 10 and the second head 14 are located farther from the wall than the first protrusion 50 and the second protrusion 54. Several methods include orienting one or more head protrusions upward (e.g., as illustrated by upward direction 42 in FIG. 2). FIG. 5 illustrates a first head protrusion 116 oriented upward. In some embodiments, the hole (e.g., 72 in FIG. 3) includes a first section, which is circular, and a second section, which is narrower (e.g., in width) than the first section. Some embodiments include inserting the central portion 112 through the first section while inserting the first head protrusion through the second section of the hole.

Some methods include inserting fasteners 74 (e.g., screws) through the bar 6 and into the wall 70. The fasteners can be positioned such that they are located inward (e.g., 38 in FIG. 3) relative to the first head 10, the second head 14, the first protrusion 50, the second protrusion 54, the platform 162, and/or the flat surface 166.

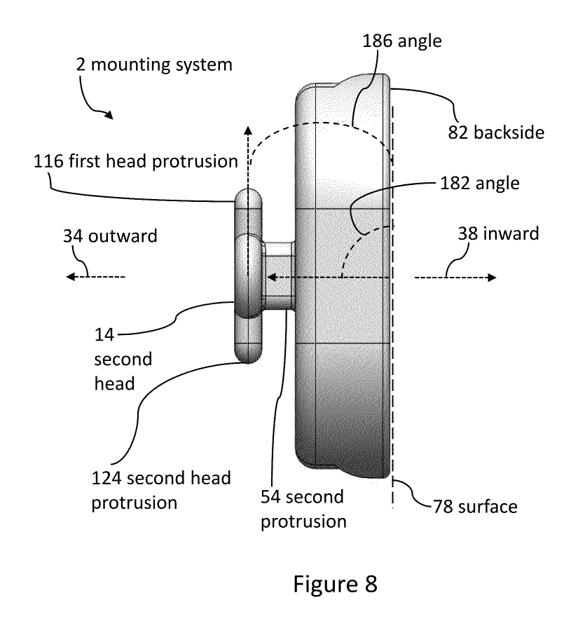

FIG. 8 illustrates a side view of a mounting system 2. The second protrusion 54 can be oriented at an angle 182 relative to the surface 78 (e.g., a wall to which the mounting system 2 is coupled). The angle 182 at which the second protrusion 54 protrudes relative to the wall can be at least 80 degrees and/or less than 100 degrees; at least 70 degrees and/or less than 110 degrees; and/or at least 45 degrees and/or less than 135 degrees.

The second head 14 can be oriented at an angle 186 relative to the surface 78 (e.g., a wall to which the mounting system 2 is coupled). The angle 186 can be between 5 degrees and negative 5 degrees; between 15 degrees and negative 15 degrees; and/or between 30 degrees and negative 30 degrees. In some embodiments, the second head 14 is oriented parallel to the surface 78 such that the angle 186 is approximately zero degrees.

In several embodiments, angles can be measured relative to the backside 82 of the mounting system 2, wherein the backside 82 is configured to be placed against a surface, such as a wall, to couple an electronic device to the surface. The second protrusion 54 can be oriented at an angle 182 relative to the backside 82. The angle 182 at which the second protrusion 54 protrudes relative to the backside 82 can be at least 80 degrees and/or less than 100 degrees; at least 70 degrees and/or less than 110 degrees; and/or at least 45 degrees and/or less than 135 degrees.

The second head 14 can be oriented at an angle 186 relative to the backside 82. The angle 186 can be between 5 degrees and negative 5 degrees; between 15 degrees and negative 15 degrees; and/or between 30 degrees and negative 30 degrees. In some embodiments, the second head 14 is oriented parallel to the backside 82 such that the angle 186 is approximately zero degrees.

In some embodiments, the angle 186 can measure the orientation of the first head protrusion 116 and/or the second head protrusion 124 relative to the backside 82 and/or relative to the surface 78. The angle 186 can be between 5 degrees and negative 5 degrees; between 15 degrees and negative 15 degrees; and/or between 30 degrees and negative 30 degrees. In some embodiments, the first head protrusion 116 and/or the second head protrusion 124 is oriented parallel to the backside 82 and/or parallel to the surface 78 such that the angle 186 is approximately zero degrees.

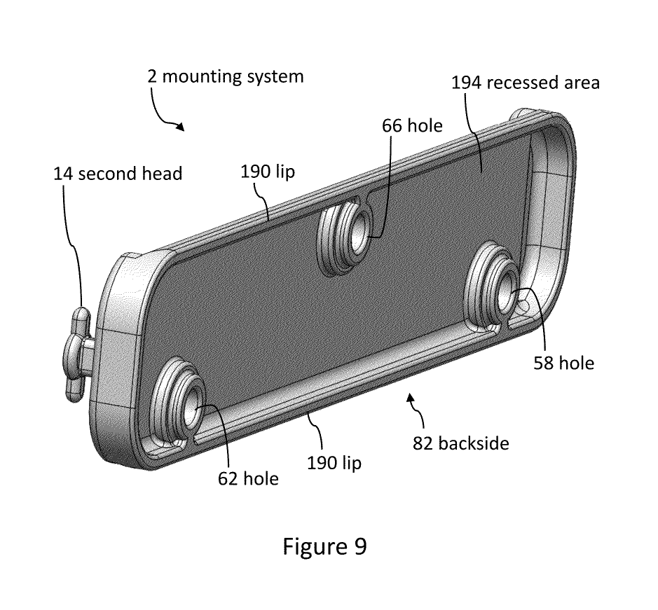

FIG. 9 illustrates a perspective view, which shows the backside 82 of the mounting system 2. In some embodiments, the backside comprises a large flat face. In the illustrated embodiment, the backside 82 comprises a lip 190 that extends around the perimeter of the mounting system 2. The backside 82 is configured to be placed against a surface, such as a wall. A large recessed area 194 in the embodiment illustrated in FIG. 9 results in the backside 82 having relatively little surface area. The lip 190 can rest against the wall 70, as illustrated in FIG. 3. The holes 58, 62, 66 can rest against the wall 70.

Although many embodiments have been described in the context of the second head 14 and the second protrusion 54, the embodiments can also be implemented in other heads and protrusions.

None of the items described herein are essential or indispensable. The steps can be modified or altered. Additional steps can be added. Any portion of any of the structures, devices, assemblies, features, steps, blocks, and/or processes disclosed and/or described in the context of one embodiment, example, flowchart, and/or diagram herein can be combined or used with or instead of any other portion of the structures, devices, assemblies, features, steps, blocks, and/or processes disclosed and/or described in the context of another embodiment. The embodiments and examples provided herein are not intended to be discrete or separate from each other. Thus, an item from one embodiment can be combined with an item from another embodiment.

The items described above may be used independently of one another or may be combined. All possible combinations and subcombinations are intended to fall within the scope of this disclosure. The method and process embodiments are not limited to any disclosed sequence. The methods and processes may be implemented without any portion of the methods and processes. For example, embodiments that are described with four steps, blocks, items, or portions can be implemented with less than four steps, blocks, items, or portions. Portions of steps, processes, and blocks may be omitted in some implementations. Multiple steps, processes, and blocks may be combined into a single step, process, or block. Items can be implemented in serial, parallel, or in any other suitable manner.

In various implementations, devices, components, and assemblies can be configured differently than described in the embodiments included herein. Features and parts can be added, removed, and/or rearranged.

As used herein, conditional language is generally intended to convey that certain embodiments include, while other embodiments do not include, certain features, elements, portions, methods, and/or steps. Examples of conditional language include “can,” “could,” “might,” “may,” “e.g.,” and the like. Conditional language is generally not intended to imply that features, elements, portions, methods, and/or steps are in any way required for one or more embodiments. The terms “comprising,” “including,” and “having” are synonymous and are used in an open-ended fashion and do not exclude additional elements, features, acts, operations, steps, and so forth.

The term “and/or” means that “and” applies to some embodiments and “or” applies to some embodiments. Thus, A, B, and/or C can be replaced with A, B, and C written in one sentence and A, B, or C written in another sentence. A, B, and/or C means that some embodiments can include A and B, some embodiments can include A and C, some embodiments can include B and C, some embodiments can include A, some embodiments can include B, some embodiments can include C, and some embodiments can include A, B, and C. The term “and/or” is used to avoid unnecessary redundancy.

Also, the term “or” is used in its inclusive sense (and not in its exclusive sense) so that when used, for example, to connect a list of elements, the term “or” means one, some, or all of the elements in the list.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require at least one of X, at least one of Y, and at least one of Z to be present.

While certain example embodiments have been described, these embodiments have been presented by way of example only, and are not intended to limit the scope of the inventions disclosed herein. Thus, nothing in the foregoing description is intended to imply that any particular feature, characteristic, step, module, or block is necessary or indispensable. Indeed, the novel methods, processes, steps, features, devices, structures, components, and systems described herein may be embodied in a variety of other forms. Furthermore, various omissions, substitutions, and changes in the form of the methods, processes, steps, features, devices, structures, components, and systems described herein may be made without departing from the spirit of the inventions disclosed herein.

The following is claimed:

1. A mounting system for coupling an electronic device to a surface, the mounting system comprising:
a bar configured to couple to the surface, wherein the bar comprises a left side and a right side;
a first protrusion that protrudes outward from the left side of the bar, wherein the first protrusion comprises a first protrusion width, a first protrusion length, and a first protrusion thickness;
a first head comprising a first head width, a first head length, and a first head thickness,
wherein the first protrusion couples the first head to the left side of the bar,
wherein the first head is configured to couple the mounting system to the device, and
wherein the first head width is greater than the first protrusion width;
a second protrusion that protrudes outward from the right side of the bar, wherein the second protrusion comprises a second protrusion width, a second protrusion length, and a second protrusion thickness; and
a second head comprising a second head width, a second head length, and a second head thickness,
wherein the second protrusion couples the second head to the right side of the bar,
wherein the second head is configured to couple the mounting system to the device, and
wherein the second head width is greater than the second protrusion width.

2. The mounting system of claim 1, wherein the first head comprises
a first central portion comprising a first central portion width, and
a first head protrusion that protrudes upward relative to the central portion, wherein the first head protrusion comprises a third width,
wherein the first central portion couples the first head protrusion to the first protrusion, and
wherein the first central portion width is at least 25 percent greater than the third width of the first head protrusion.

3. The mounting system of claim 2, wherein the first central portion is approximately circular.

4. The mounting system of claim 2, wherein the first head comprises a second head protrusion that protrudes downward relative to the first central portion, wherein the second head protrusion comprises a fourth width, wherein the first central portion couples the second head protrusion to the first protrusion, and wherein the first central portion width is at least 40 percent greater than the fourth width of the second head protrusion.

5. The mounting system of claim 4, wherein first head protrusion comprises an upward end and the second head protrusion comprises a downward end, wherein the upward end is curved and the downward end is curved, and wherein the third width of the first head protrusion is within plus or minus 10 percent of the fourth width of the second head protrusion.

6. The mounting system of claim 2, wherein the first central portion comprises a left side and a right side, wherein the left side of the first central portion is curved and the right side of the first central portion is curved, and wherein the first head protrusion comprises a left side and a right side, wherein the left side of the first head protrusion is straight and the right side of the first head protrusion is straight.

7. The mounting system of claim 6, wherein first head protrusion and the second head protrusion are coplanar.

8. The mounting system of claim 2, wherein the second head comprises
a second central portion comprising a second central portion width, and
a third head protrusion that protrudes upward relative to the second central portion, wherein the third head protrusion comprises a fifth width,
wherein the second central portion couples the third head protrusion to the second protrusion, and
wherein the second central portion width is at least 70 percent greater than the fifth width of the third head protrusion.

9. The mounting system of claim 1, wherein
the first protrusion length is at least fifty percent larger than the first protrusion width,
the second protrusion length is at least fifty percent larger than the second protrusion width,
the first protrusion thickness is less than seven millimeters, and
the second protrusion thickness is less than seven millimeters.

10. The mounting system of claim 1, wherein the first head length is at least thirty percent larger than the first head width, and the first head thickness is less than seven millimeters.

11. The mounting system of claim 1, wherein the bar comprises a first hole in the left side, wherein the first hole is configured to enable a first screw to couple the bar to a wall of a building and the bar comprises a second hole in the right side, wherein the second hole is configured to enable a second screw to couple the bar to the wall.

12. The mounting system of claim 11, wherein the first hole is located to the right of the first head and the second hole is located to the left of the second head.

13. The mounting system of claim 1, further comprising a first platform having a first flat outward-facing surface, wherein the first platform couples the first protrusion to the bar, and further comprising a second platform having a second flat outward-facing surface, wherein the second platform couples the second protrusion to the bar, and wherein the first and second platforms protrude outward from the bar to enable airflow between the device and the bar.

14. A mounting system for coupling an electronic device to a wall, the mounting system comprising:
a bar configured to couple to an external surface of the wall such that the bar protrudes outwardly from the wall, wherein the bar comprises a left portion and a right portion;
a first anchor coupled to the left portion of the bar; and
a second anchor coupled to the right portion of the bar,
wherein the first anchor is configured to couple the mounting system to the device via a first hole in the device and the second anchor is configured to couple the mounting system to the device via a second hole in the device,
wherein the first anchor comprises a first head configured to enter the first hole, wherein the first head comprises a first main portion and a first finger that protrudes upward relative to the first main portion, wherein the first main portion is at least fifty percent wider than the first finger, and
wherein the second anchor comprises a second head configured to enter the second hole, wherein the second head comprises a second main portion and a second finger that protrudes upward relative to the second main portion, wherein the second main portion is at least fifty percent wider than the second finger.

15. A method for coupling an electronic device comprising a first hole and a second hole to a wall, the method comprising:
molding a bar comprising a left side, a right side, and a third hole;
coupling a first protrusion to the left side of the bar and coupling a second protrusion to the right side of the bar;
coupling a first head to the first protrusion and coupling a second head to the second protrusion such that the first head and the second head are located between 40 millimeters and 290 millimeters apart;
inserting a screw through the third hole and coupling the bar to the wall via the screw;
orienting the bar such that the first protrusion and the second protrusion protrude outward away from the wall;
orienting the bar such that the first head and the second head are located farther from the wall than the first protrusion and the second protrusion; and
inserting the first head into the first hole of the electronic device and inserting the second head into the second hole of the electronic device.

16. The mounting system of claim 15, further comprising orienting the bar horizontally.

17. The mounting system of claim 15, wherein the wall is a ceiling.

18. The mounting system of claim 15, further comprising coupling the electronic device between the first head and a first platform having a first flat outward-facing surface and coupling the electronic device between the second head and a second platform having a second flat outward-facing surface to form a gap between the electronic device and at least a majority of the bar.
